(19) United States
(12) Patent Application Publication
(10) Pub. No.: US 2015/0206976 A1
(43) Pub. Date: Jul. 23, 2015

(54) THIN FILM TRANSISTOR AND METHOD FOR MANUFACTURING THE SAME

(71) Applicant: Samsung Display Co., Ltd., Yongin-city (KR)

(72) Inventors: Jae Won SONG, Seoul (KR); Young Joo CHOI, Anyang-si (KR)

(73) Assignee: Samsung Display Co., Ltd., Yongin-city (KR)

(21) Appl. No.: 14/283,063

(22) Filed: May 20, 2014

(30) Foreign Application Priority Data
Jan. 17, 2014 (KR) 10-2014-0006125

(51) Int. Cl. H01L 29/786; H01L 29/66

(52) U.S. Cl. CPC H01L 29/7869; H01L 29/66742

(57) ABSTRACT

A thin film transistor includes a gate electrode disposed on a substrate, a gate insulating layer disposed on the gate electrode and the substrate, an oxide semiconductor pattern disposed on the gate insulating layer, wherein a part of the oxide semiconductor overlaps the gate electrode, a source electrode disposed on a part of the oxide semiconductor pattern, and a drain electrode disposed on a part of the oxide semiconductor pattern spaced apart from the source electrode, wherein a thickness of the gate insulating layer in a channel region, the channel region overlapping the gate electrode, is thinner than a thickness of the gate insulating layer in a remaining region, the remaining region other than the channel region.

### CROSS-REFERENCE TO RELATED APPLICATIONS

This application claims priority from and the benefit of Korean Patent Application No. 10-2014-0006125, filed on Jan. 17, 2014, which is hereby incorporated by reference for all purposes as if fully set forth herein.

### BACKGROUND

1. Field

Aspects of the present invention relate to a thin film transistor, a method for manufacturing the same, and a display device using the same.

2. Discussion of the Background

In general, a thin film transistor (TFT) is used as a switching element for independently driving each pixel in a flat-panel display, such as a liquid crystal display or an organic light emitting display. A thin film transistor display plate that includes the thin film transistor additionally includes a gate line transferring a gate signal to the thin film transistor, a data line transferring a data signal to the thin film transistor, and a pixel electrode connected to the thin film transistor.

The thin film transistor includes a gate electrode connected to the gate line, a source electrode connected to the data line, a drain electrode connected to the pixel electrode, and a semiconductor layer positioned on the gate electrode between the source electrode and the drain electrode, and transfers the data signal from the data line to the pixel electrode according to the gate signal from the gate line.

In this case, the semiconductor layer of the thin film transistor is made of polycrystalline silicon (or polysilicon), amorphous silicon, or oxide semiconductor.

The source and drain electrodes of the thin film transistor, between which a gate insulating layer is interposed, partially overlap the gate electrode to form parasitic capacitance or may form parasitic capacitance at a corner portion of the gate electrode, and thus the load of the gate line is increased which makes the high-speed operation difficult.

The above information disclosed in this Background section is only for enhancement of understanding of the background of the invention and therefore it may contain information that does not form any part of the prior art nor what the prior art may suggest to a person of ordinary skill in the art.

### SUMMARY

Exemplary embodiments of the present invention provide a thin film transistor and a method for manufacturing the same, which can reduce power consumption and can perform high-speed operation through reduction of parasitic capacitance.

Additional advantages, subjects, and features of the invention will be set forth in part in the description which follows and in part will become apparent to those having ordinary skill in the art upon examination of the following or may be learned from practice of the invention.

An exemplary embodiment of the present invention provides a thin film transistor including a gate electrode disposed on a substrate, a gate insulating layer disposed on the gate electrode and the substrate, an oxide semiconductor pattern disposed on the gate insulating layer, wherein a part of the oxide semiconductor overlaps the gate electrode, a source electrode disposed on a part of the oxide semiconductor pattern, and a drain electrode disposed on a part of the oxide semiconductor pattern spaced apart from the source electrode, wherein a thickness of the gate insulating layer in a channel region, the channel region overlapping the gate electrode, is thinner than a thickness of the gate insulating layer in a remaining region, the remaining region being region other than the channel region.

An exemplary embodiment of the present invention provides a thin film transistor including a gate electrode disposed on a substrate, a gate insulating layer disposed on the gate electrode and the substrate, an oxide semiconductor pattern disposed on the gate insulating layer, wherein a part of the gate electrode overlaps the gate electrode, a source electrode disposed on a part of the oxide semiconductor pattern, and a drain electrode disposed on a part of the oxide semiconductor pattern spaced apart from the source electrode, wherein the gate insulating layer in a channel region, the channel region overlapping the gate electrode, and the gate insulating layer in a remaining region, the remaining region being other than the channel region, have different layer composition from components.

An exemplary embodiment of the present invention provides a method for manufacturing a thin film transistor, including forming a gate electrode on a substrate, forming a gate insulating layer on the substrate and the gate electrode, etching the gate insulating layer in a channel region, the channel region overlapping the gate electrode, forming an oxide semiconductor pattern on the gate insulating layer, wherein a part of the oxide semiconductor overlaps, forming a source electrode and a drain electrode on the oxide semiconductor pattern, and forming an encapsulation layer on the source electrode, the drain electrode, the oxide semiconductor pattern, and the gate insulating layer.

An exemplary embodiment of the present invention also provides a method for manufacturing a thin film transistor, including forming a gate electrode on a substrate, forming a silicon nitride layer on the gate electrode at least partially, forming a silicon oxide layer on the substrate, the gate electrode, and the silicon nitride layer, etching the silicon oxide layer in a channel region, the channel region overlapping the gate electrode, forming an oxide semiconductor pattern on the gate insulating layer, wherein a part of the oxide semiconductor overlaps the gate electrode, forming a source electrode and a drain electrode on the oxide semiconductor pattern, and forming an encapsulation layer on the source electrode, the drain electrode, the oxide semiconductor pattern, and the gate insulating layer.

According to embodiments of the present invention, the power consumption can be reduced through reduction of the parasitic capacitance and can offset a performance difference with the related art through reduction of ion deterioration of a thin film transistor channel portion. Further, through reduction of the parasitic capacitance, it becomes possible to provide the thin film transistor that can perform high-speed operation. The effects according to the present invention are not limited to the contents as exemplified above, but more various effects are described in the specification of the present invention.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

The above and other objects, features and advantages of the present invention will be more apparent from the following detailed description taken in conjunction with the accompanying drawings.

FIG. 1 is a schematic cross-sectional view illustrating a thin film transistor according to exemplary embodiments of the present invention.

FIG. 2 is an enlarged view of a source electrode and a drain electrode in FIG. 1.

FIG. 3 is a schematic cross-sectional view illustrating a thin film transistor according to exemplary embodiments of the present invention.

FIG. 4 is a schematic cross-sectional view illustrating a thin film transistor according to still exemplary embodiments of the present invention.

FIGS. 5, 6, 7, 8, 9, 10, 11, 12, 13, 14, 15, 16, 17, 18, and 19 are schematic cross-sectional views, explaining a method for manufacturing a thin film transistor according to exemplary embodiments of the present invention illustrated in FIG. 1.

FIGS. 20, 21, and 22 are schematic cross-sectional views of forming a gate insulating layer, explaining a method for manufacturing a thin film transistor according to exemplary embodiments of the present invention illustrated in FIG. 3.

FIGS. 23, 24, 25, and 26 are schematic cross-sectional views of forming a gate insulating layer, explaining a method for manufacturing a thin film transistor according to exemplary embodiments of the present invention.

### DETAILED DESCRIPTION OF THE EXEMPLARY EMBODIMENTS

Advantages and features of the present invention and methods of accomplishing the same may be understood more readily by reference to the following detailed description of embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items. It will also be understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Hereinafter, embodiments of the present invention will be described in detail with reference to the accompanying drawings.

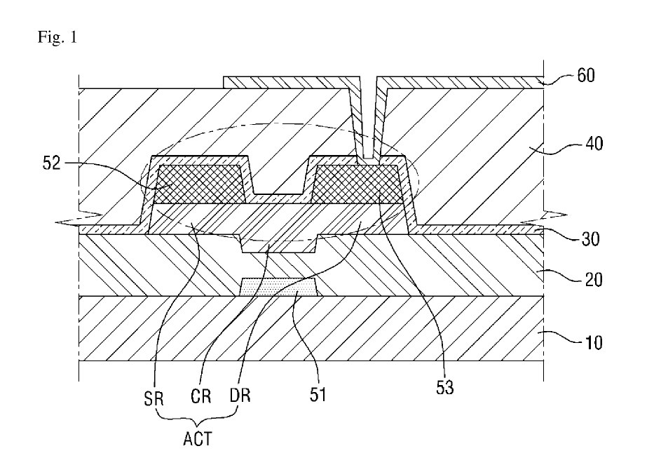

FIG. 1 is a schematic cross-sectional view illustrating a thin film transistor according to exemplary embodiments of the present invention.

Referring to FIG. 1, a thin film transistor may include a substrate 10, a gate electrode 51, a gate insulating layer 20, an oxide semiconductor pattern ACT, a source electrode 52, a drain electrode 53, and an encapsulation layer 30.

The substrate 10 may be in a plate shape, planar, or curved shape, and support other structures formed on the substrate 10. The substrate 10 may be formed of an insulating material. For example, the substrate 10 may be formed of glass, polyethyleneterepthalate (PET), polycarbonate (PC), polyethersulfone (PES), polyimide (PI), or polymethylmetharcylate (PMMA), but is not limited thereto. In exemplary embodiments, the substrate 10 may be formed of a material having flexibility.

The gate electrode 51 may be formed on the substrate 10. In exemplary embodiments, a buffer layer (not illustrated) may be additionally formed between the substrate 10 and the gate electrode 51. The buffer layer may prevent permeation of impurity elements and planarize an upper surface of the substrate 10. The buffer layer may be formed of various materials that can perform the above-described functions. For example, the buffer layer may be made of any one of silicon nitride, silicon oxide, and silicon oxynitride, but is not limited thereto.

The gate insulating layer 20 may be formed on the substrate 10 and the gate electrode 51. The gate insulating layer may insulate the oxide semiconductor pattern ACT from the gate electrode 51, and may be formed to cover the gate electrode 51.

The oxide semiconductor pattern ACT may include single oxide, such as gallium oxide, indium oxide, tin oxide, or zinc oxide, or a multi-component metal oxide, such as gallium-indium-zinc oxide (GIZO), indium-gallium-tin oxide (IGTO), indium-zinc oxide (IZO), or zinc-aluminum oxide.

The source electrode 52 may be disposed on at least a portion of the oxide semiconductor pattern ACT, and the drain electrode 53 may be disposed on at least a portion of the oxide semiconductor pattern ACT spaced apart from the source electrode 52.

The oxide semiconductor pattern ACT may include a channel region CR that overlaps at least a portion of the gate electrode 51, and a source region SR and a drain region DR, disposed on each side of the channel region CR and respectively contacting the source electrode 52 and the drain electrode 53.

The encapsulation layer 30 may be formed on the source electrode 52, the drain electrode 53, the oxide semiconductor pattern ACT, and the gate insulating layer 20. The encapsulation layer 30 may be formed of silicon nitride or silicon oxide, but is not limited thereto.

For use in a display device, a planarization layer 40 and a pixel electrode 60 may be additionally included on an upper portion of the thin film transistor according to an embodiment of the present invention.

The planarization layer 40 may be disposed on the encapsulation layer 30. An upper surface of the planarization layer 40 may be formed to have an even surface. The planarization layer 40 may be formed of an insulating material. For example, the planarization layer 40 may be formed of at least one of polyacrylates resin, epoxy resin, phenolic resin, polyamides resin, polyimides resin, unsaturated polyesters resin, poly phenylenethers resin, poly phenylenesuffides resin, and benzocyclobutene (BCB), but is not limited thereto.

The pixel electrode 60 may be deposited on the planarization layer 40. A contact hole may be formed on the encapsulation layer 30 and the planarization layer 40. The contact hole may expose the drain electrode 53, and the pixel electrode 60 and the drain electrode 53 may be electrically connected to each other through the contact hole.

The thickness of one region of the gate insulating layer 20, which overlaps the gate electrode 51, may be thinner than the thickness of the remaining region, and in this case, the gate insulating layer 20 may be made of silicon oxide or a mixture of silicon oxide and silicon nitride.

In the related art, due to the relatively high processing time when silicon oxide is used, silicon nitride is mainly used, and silicon oxide is used for the surface that comes in contact with the oxide semiconductor pattern. Since silicon nitride has permittivity relatively higher than the permittivity of silicon oxide, ions can be easily secured in a channel region when silicon nitride was used. However, use of silicon nitride may increase the parasitic capacitance. Accordingly, power consumption of the thin film transistor is increased, and it becomes difficult to operate the thin film transistor in high-speed.

If the structure of the gate insulating layer 20 is formed as illustrated in FIG. 1, the parasitic capacitance can be reduced by using the silicon oxide, and ions can be secured at the same level in the channel region to decrease parasitic capacitance.

The capacitance C may be defined in Equation 1 below.

$$C = ɛ \frac{A}{t} \qquad ( 1 )$$

In Equation 1, ε denotes permittivity, t denotes thickness, and A denotes an area.

In other words, the capacitance C is directly proportional to the permittivity and the area, and is inversely proportional to the thickness. Accordingly, the permittivity may be reduced in a region where the parasitic capacitance is generated and the capacitance in the channel region may be increased.

For this reason, a material having relatively low permittivity may be mainly used as the gate insulating layer 20 to reduce the parasitic capacitance, and the thickness of the gate insulating layer 20 may be reduced in the channel region which overlaps the gate electrode 51 to increase the capacitance in the channel region.

In exemplary embodiments, the gate insulating layer 20 may be formed as a single layer of silicon oxide. In exemplary embodiments, the gate insulating layer 20 may be formed of a mixture of silicon oxide and silicon nitride. Even in this case, the overall permittivity of the gate insulating layer 20 may be reduced by increasing the thickness of the silicon oxide.

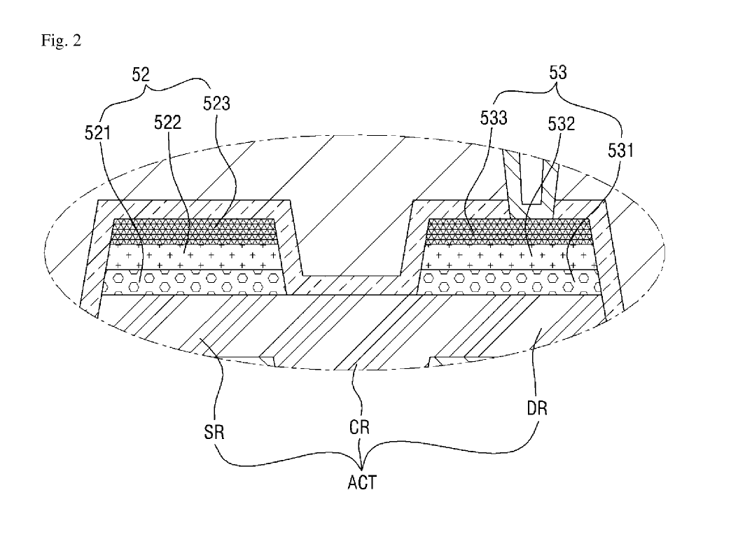

FIG. 2 is an enlarged view of a source electrode and a drain electrode in FIG. 1.

Referring to FIG. 2, a source electrode 52 and a drain electrode 53 may be formed in a multilayer structure.

In an exemplary embodiment, the source electrode 52 and the drain electrode 53 may be formed in a three-layer structure, but are not limited thereto. The source electrode 52 and the drain electrode 53 may also be formed in a two-layer structure or in a four or more layer structure.

The source electrode 52 and the drain electrode 53 may respectively include first barrier layers 521 and 531, metal wiring layers 522 and 532, and second barrier layers 523 and 533. The first barrier layers 521 and 531 may prevent the metal wiring layers 522 and 532 from being oxidized from direct contact with the oxide semiconductor pattern ACT. The second barrier layers 523 and 533 may prevent the metal wiring layers 522 and 532 from being oxidized from direct contact with the encapsulation layer 30.

In an exemplary embodiment, one of the first barrier layers 521 and 531 and the second barrier layers 523 and 533 may be omitted.

The first barrier layers 521 and 531 and the second barrier layers 523 and 533 may be made of, for example, metal oxide, but are not limited thereto as far as they may provide the above-described effects.

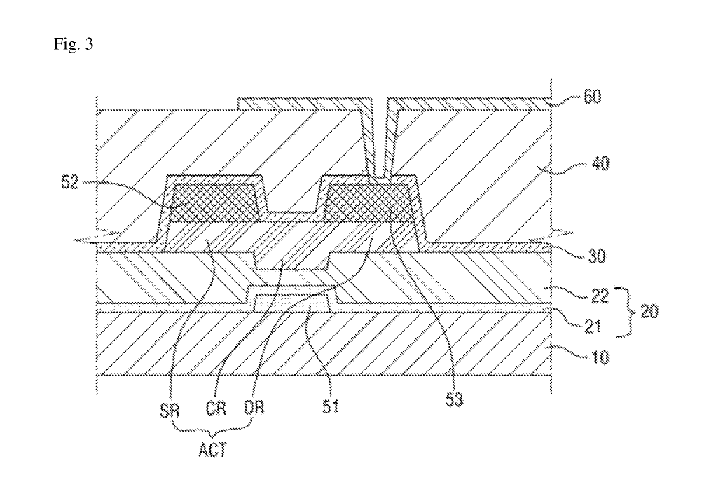

FIG. 3 is a schematic cross-sectional view illustrating a thin film transistor according to an embodiment of the present invention.

Referring to FIG. 3, a gate insulating layer 20 is composed of two layers, that is, a silicon nitride layer 21 and a silicon oxide layer 22. The silicon nitride layer 21 is disposed on the substrate 10 and the gate electrode 51 contacting the gate electrode 51, and the silicon oxide layer 22 is disposed between the silicon nitride layer 21 and the oxide semiconductor pattern ACT contacting the oxide semiconductor pattern ACT.

The thickness of the channel region of the silicon oxide layer 22, which overlaps the gate electrode 51, may be thinner than the thickness of the remaining region. In a region where the silicon oxide layer 22 does not overlap the gate electrode 51, the thickness of the silicon oxide layer 22 may be relatively thicker than the thickness of the silicon nitride layer 21. In this case, as described above with reference to FIG. 1, since the permittivity can be relatively reduced in the region other than the channel region, the parasitic capacitance can be lowered and the power consumption can be reduced. Meanwhile, by reducing the thickness of the channel region, the capacitance in the channel region can be formed relatively higher than the parasitic capacitance, and thus ions can be easily secured in the channel region.

Since other configurations except for the configuration of the gate insulating layer 20 are the same as those as described above with reference to FIG. 1, the duplicate explanation thereof will be omitted.

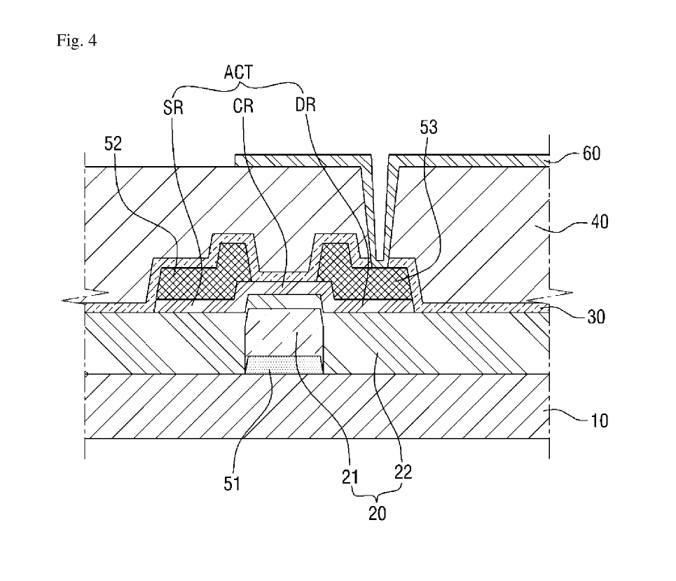

FIG. 4 is a schematic cross-sectional view illustrating a thin film transistor according to still an embodiment of the present invention.

Referring to FIG. 4, main configuration components of the gate insulating layer 20 within the channel region may be different from those of the remaining region thereof.

The channel region of the gate insulating layer 20 may include a double-layer structure of a silicon nitride layer 21 and a silicon oxide layer 22, and the remaining region may include the silicon oxide layer 22.

The channel region includes the silicon nitride layer 21 having relatively high permittivity as a main configuration component, and the silicon oxide layer 22 may be thinly formed between the silicon nitride layer 21 and the oxide semiconductor pattern ACT. The region other than the channel region may include the silicon oxide layer 22 having relatively low permittivity as a main configuration component.

FIG. 4 illustrates that the region other than the channel region is a single layer of the silicon oxide layer 22. However, according to another exemplary embodiment, the region other than the channel region may also have a double-layer structure of the silicon nitride layer 21 and the silicon oxide layer 22. According to this exemplary embodiment, the permittivity of the channel region may be set to be different from the permittivity of the region other than the channel region, and the capacitance of the channel region may be set different from the capacitance of the region other than the channel region even if the both regions have the same height.

Since other configurations except for the configuration of the gate insulating layer 20 are the same as those as described above with reference to FIG. 1, the duplicate explanation thereof will be omitted.

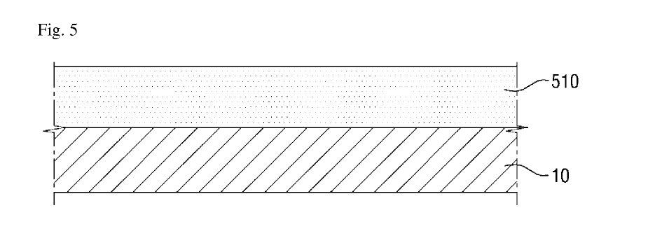

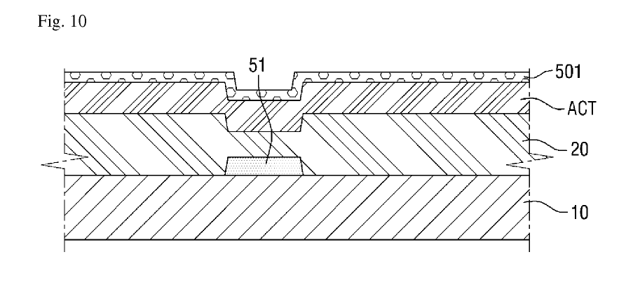

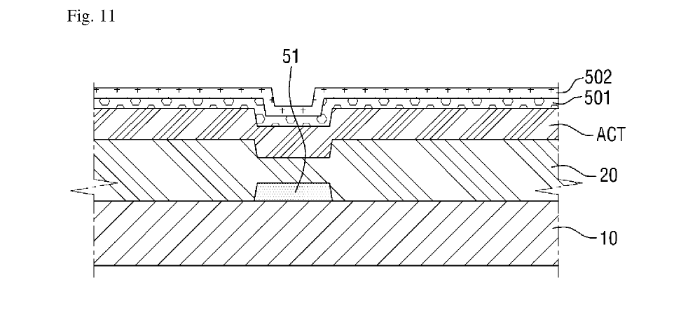

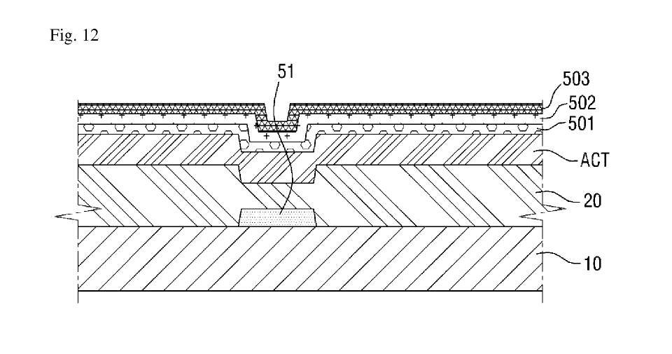

FIGS. 5, 6, 7, 8, 9, 10, 11, 12, 13, 14, 15, 16, 17, 18, and 19 are schematic cross-sectional views explaining a method for manufacturing a thin film transistor according to exemplary embodiments of the present invention illustrated in FIG. 1.

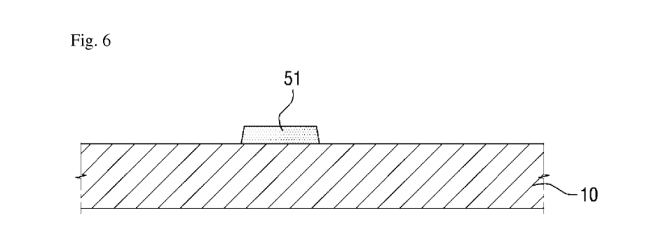

Specifically, FIGS. 5 and 6 are schematic cross-sectional views explaining a method for forming the gate electrode 51.

Referring to FIGS. 5 and 6, a metal layer 510 for the gate electrode 51 may be disposed on a substrate 10, and then the gate electrode 51 may be formed through patterning of the metal layer 510. The metal layer 510 for the gate electrode may be formed through deposition, but the method of disposing the metal layer 510 is not limited thereto. The method for patterning the metal layer 510 may include, for example, etching after photoresist is formed, but is not limited thereto. According another exemplary embodiment, the gate electrode 51 may be directly deposited using a fine mask.

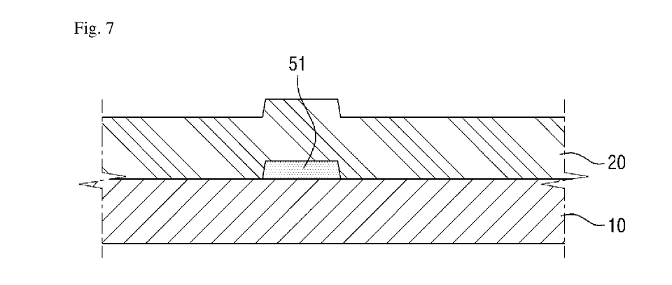

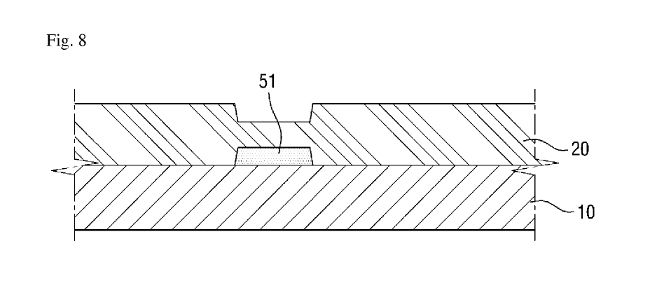

FIGS. 7 and 8 are schematic cross-sectional views explaining forming of the gate insulating layer 20.

Referring to FIGS. 7 and 8, the gate insulating layer 20 may be formed on the substrate 10 and the gate electrode 51, and then the gate insulating layer 20 that is formed on the channel region may be etched.

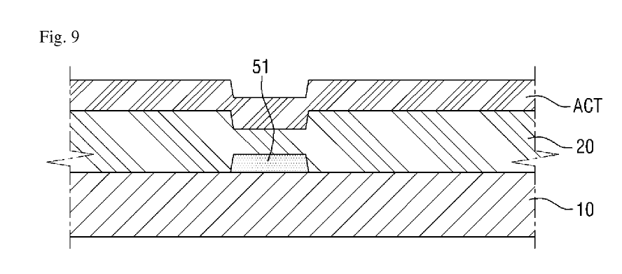

FIGS. 9, 10, 11, 12, 13, and 14 are schematic cross-sectional views explaining forming of the oxide semiconductor pattern ACT, the source electrode 52, and the drain electrode 53.

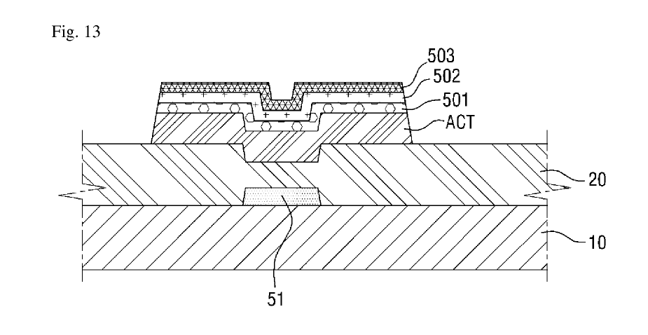

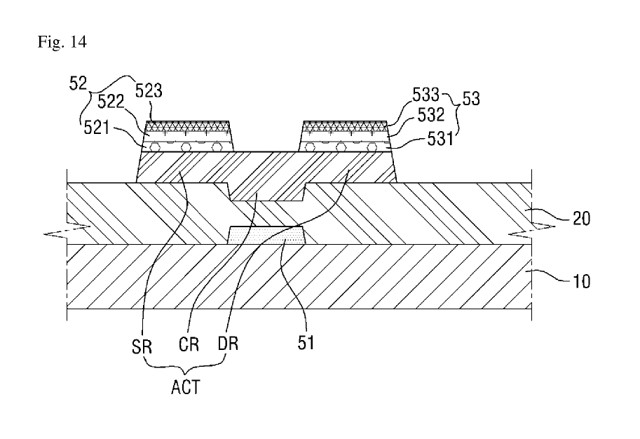

Referring to FIGS. 9, 10, 11, and 12, an oxide semiconductor layer ACT, a first barrier layer 501, a metal wiring layer 502, and a second barrier layer 503 may be successively stacked on the gate insulating layer 20. Referring to FIG. 13, the oxide semiconductor pattern ACT may be formed through primary etching. Referring to FIG. 14, a source electrode 52 and a drain electrode 53 may be formed through secondary etching.

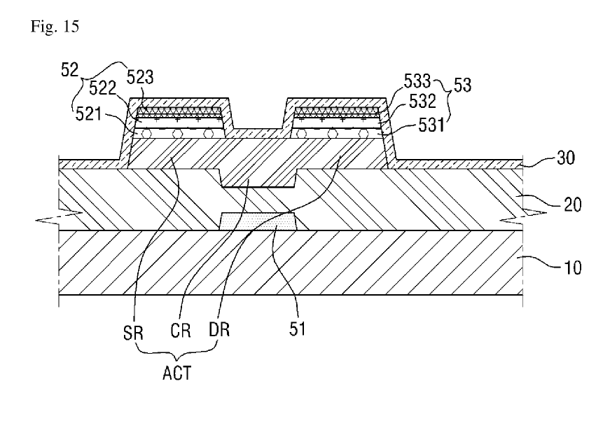

FIGS. 15, 16, 17, 18, and 19 are schematic cross-sectional views explaining forming of the encapsulation layer 30, the planarization layer 40, and the pixel electrode 60.

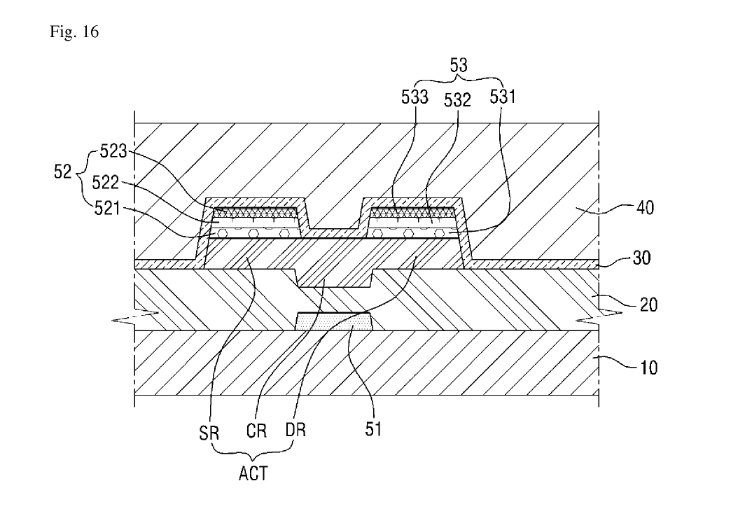

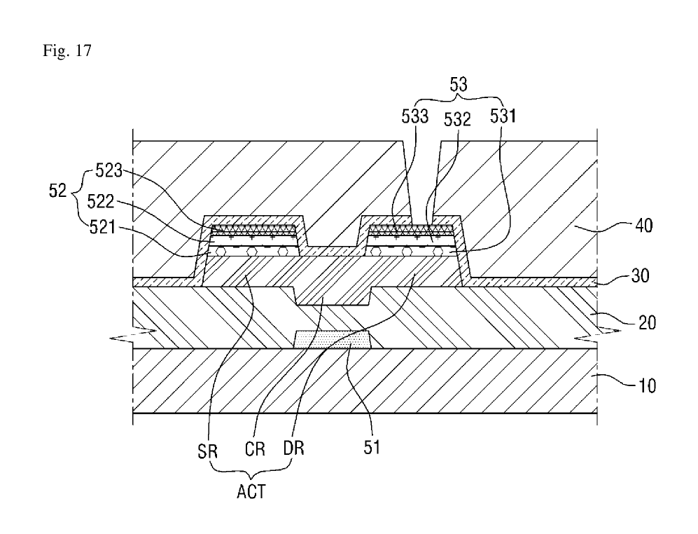

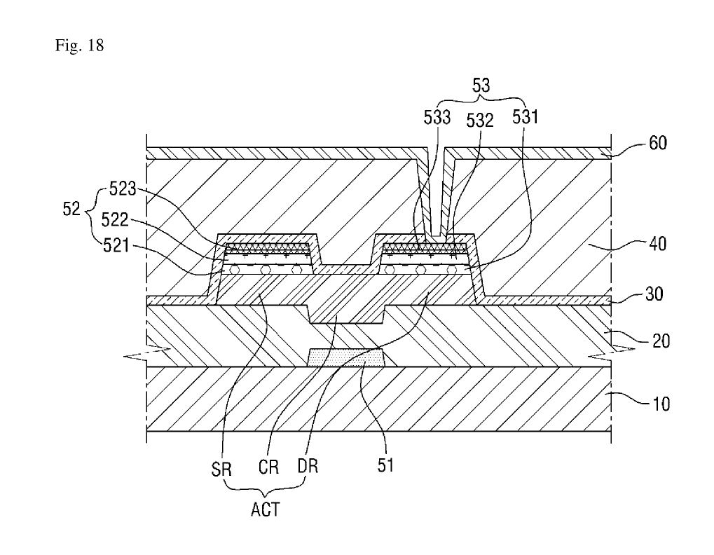

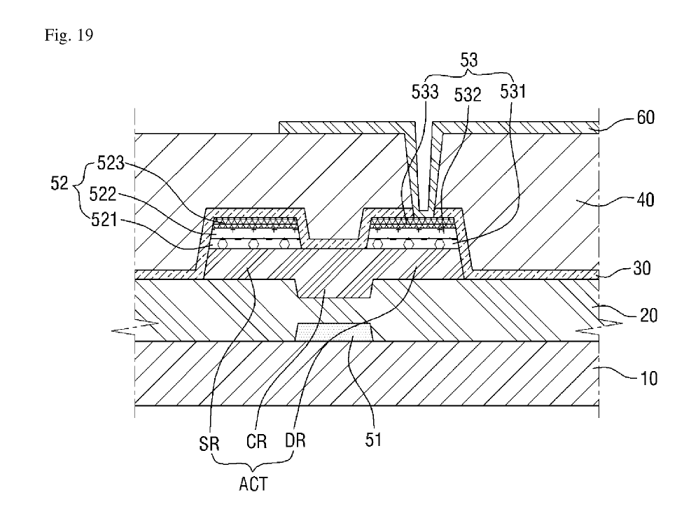

Referring to FIG. 15, the encapsulation layer 30 may be formed on the source electrode 52, the drain electrode 53, the oxide semiconductor pattern ACT, and the gate insulating layer 20. Referring to FIG. 16, the planarization layer 40 may be formed on the encapsulation layer 30. Thereafter, referring to FIG. 17, a contact hole may be formed by etching a region that overlaps the drain electrode 53. Referring to FIGS. 18 and 19, the pixel electrode 60 may be formed, and then the pixel electrode 60 may be patterned through etching of the pixel electrode 60.

The encapsulation layer 30, the planarization layer 40, and the pixel electrode 60 may be formed using any one of deposition methods, for instance, a photo mask with photoresist, but is not limited thereto.

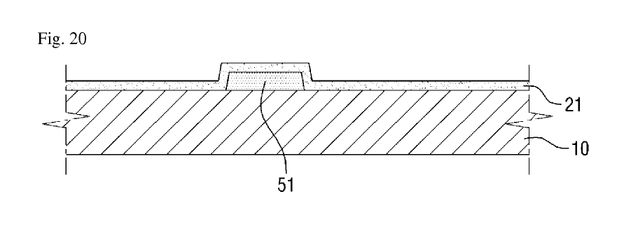

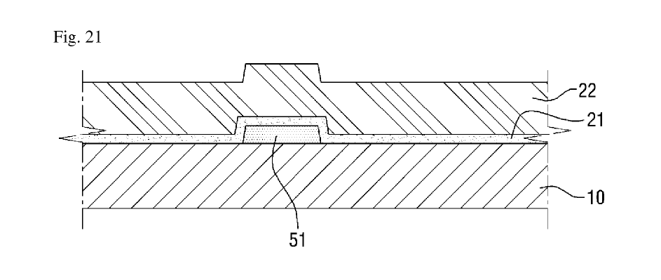

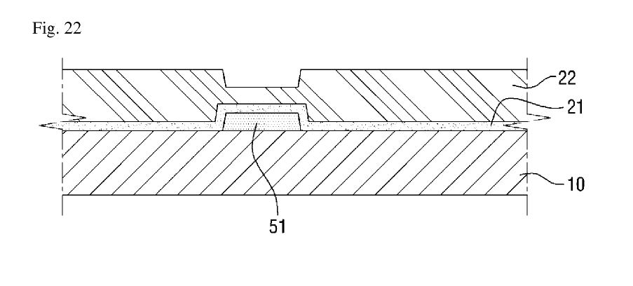

FIGS. 20, 21, and 22 are schematic cross-sectional views of forming a gate insulating layer, explaining a method for manufacturing a thin film transistor according to an embodiment of the present invention illustrated in FIG. 3. Specifically, FIGS. 20, 21, and 22 are schematic cross-sectional views explaining forming of a gate insulating layer 20.

Referring to FIGS. 20, 21, and 22, the silicon nitride layer 21 may be formed on the substrate 10 and the gate electrode 51, the silicon oxide layer 22 may be formed on the silicon nitride layer 21, and then the silicon oxide layer 22 which is formed on the channel region may be etched.

Although not illustrated in FIGS. 20, 21, and 22, in another exemplary embodiment, parts of the silicon oxide layer 22 and the silicon nitride layer 21 on the channel region may be etched.

Since the remaining operations other than the forming of the gate insulating layer 20 are the same as those as described above with reference to FIGS. 5, 6, 9, 10, 11, 12, 13, 14, 15, 16, 17, 18, and 19, the duplicate explanation thereof will be omitted.

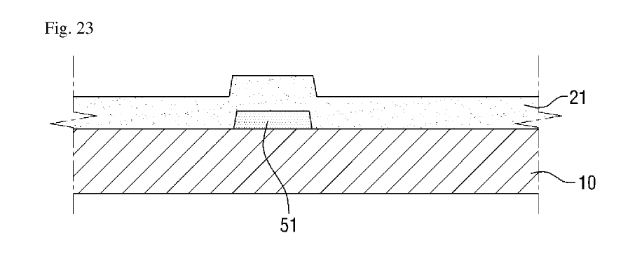

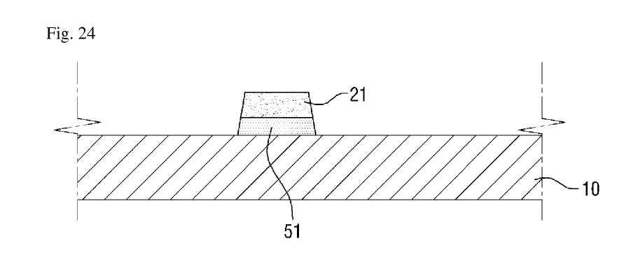

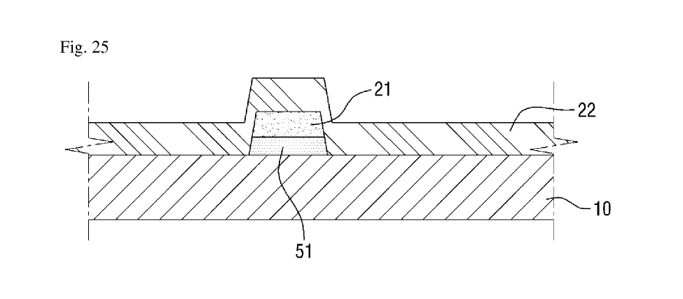

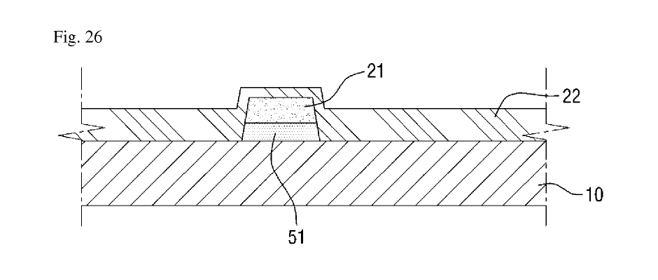

FIGS. 23, 24, 25, and 26 are schematic cross-sectional views of forming a gate insulating layer, explaining a method for manufacturing a thin film transistor according to exemplary embodiments of the present invention illustrated in FIG. 4. Specifically, FIGS. 23, 24, 25, and 26 are schematic cross-sectional views explaining forming of a gate insulating layer 20.

Referring to the drawings, the silicon nitride layer 21 may be disposed on the substrate 10 and the gate electrode 51. The silicon nitride layer 21 may be patterned so that the silicon nitride layer 21 in the channel region remains, the silicon oxide layer 22 may be disposed, and then the silicon oxide layer 22 formed on the channel region may be etched.

In an exemplary embodiment, the silicon nitride layer 21 on the region other than the channel region may be etched partially, and some of the silicon nitride layer 21 may remain. In this case, the gate insulating layer 20 is entirely formed as a double-layer of the silicon nitride layer 21 and the silicon oxide layer 22, but the channel region and the region other than the channel region may have different layer configuration.

Since the remaining operations except for the forming of the gate insulating layer 20 are the same as those as described above with reference to FIGS. 5, 6, and 9, 10, 11, 12, 13, 14, 15, 16, 17, 18, and 19, the duplicate explanation thereof will be omitted.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation. Thus, it is intended that the present invention cover the modifications and variations of this invention provided they come within the scope of the appended claims and their equivalents.

What is claimed is:

1. A thin film transistor, comprising:
a gate electrode disposed on a substrate;
a gate insulating layer disposed on the gate electrode and the substrate;
an oxide semiconductor pattern disposed on the gate insulating layer, wherein a part of the oxide semiconductor overlaps the gate electrode;
a source electrode disposed on a part of the oxide semiconductor pattern; and
a drain electrode disposed on a part of the oxide semiconductor pattern spaced apart from the source electrode,
wherein a thickness of the gate insulating layer in a channel region, the channel region overlapping the gate electrode, is thinner than a thickness of the gate insulating layer in a remaining region, the remaining region being other than the channel region.

2. The thin film transistor of claim 1, wherein the gate insulating layer is a single layer of silicon oxide.

3. The thin film transistor of claim 1, wherein the gate insulating layer comprises a silicon oxide layer and a silicon nitride layer.

4. The thin film transistor of claim 1, wherein
the gate insulating layer comprises a silicon nitride layer and a silicon oxide layer,
and a thickness of the silicon oxide layer in the channel region is thinner than a thickness of the silicon oxide layer in the remaining region.

5. The thin film transistor of claim 4, wherein
the silicon nitride layer is disposed on the gate electrode and the substrate contacting the gate electrode, and
the silicon oxide layer is disposed on the silicon nitride layer contacting the oxide semiconductor layer.

6. The thin film transistor of claim 4, wherein in the remaining region, the thickness of the silicon oxide layer is thicker than the thickness of the silicon nitride layer.

7. A thin film transistor, comprising:
a gate electrode disposed on a substrate;
a gate insulating layer disposed on the gate electrode and the substrate;
an oxide semiconductor pattern disposed on the gate insulating layer, wherein a part of the gate electrode overlaps the gate electrode;
a source electrode disposed on a part of the oxide semiconductor pattern; and
a drain electrode disposed on a part of the oxide semiconductor pattern spaced apart from the source electrode,
wherein the gate insulating layer in a channel region, the channel region overlapping the gate electrode, and the gate insulating layer in a remaining region, the remaining region being other than the channel region, have different compositions from each other.

8. The thin film transistor of claim 7, wherein the gate insulating layer comprises a silicon oxide layer and a silicon nitride layer.

9. The thin film transistor of claim 8, wherein the gate insulating layer in the remaining region comprises a single silicon oxide layer.

10. The thin film transistor of claim 7, wherein
the gate insulating layer in the remaining region comprises a silicon nitride layer and a silicon oxide layer, and
a thickness of the silicon oxide layer is thicker than a thickness of the silicon nitride layer.

11. The thin film transistor of claim 7, wherein
the gate insulating layer in the channel region comprises a silicon nitride layer and a silicon oxide layer, and
a thickness of the silicon oxide layer is thinner than a thickness of the silicon nitride layer.

12. The thin film transistor of claim 11, wherein
the silicon nitride layer is disposed on the gate electrode contacting the gate electrode, and
the silicon oxide layer is disposed on the silicon nitride contacting the oxide semiconductor layer.

13. A method for manufacturing a thin film transistor, comprising:
forming a gate electrode on a substrate;
forming a gate insulating layer on the substrate and the gate electrode;
etching the gate insulating layer in a channel region, the channel region overlapping the gate electrode; forming an oxide semiconductor pattern on the gate insulating layer, wherein a part of the oxide semiconductor overlaps;
forming a source electrode and a drain electrode on the oxide semiconductor pattern; and
forming an encapsulation layer on the source electrode, the drain electrode, the oxide semiconductor pattern, and the gate insulating layer.

14. The method of claim 13, wherein the forming the gate insulating layer comprises forming a silicon oxide layer and a silicon nitride layer.

15. The method of claim 13, wherein the forming the gate insulating layer comprises:
forming a silicon nitride layer; and
forming a silicon oxide layer on the silicon nitride layer.

16. The method of claim 15, wherein a thickness of the silicon oxide layer is thicker than a thickness of the silicon nitride layer.

17. The method of claim 16, wherein the etching the gate insulating layer comprises etching a part of the silicon oxide layer.

18. A method for manufacturing a thin film transistor, comprising:
forming a gate electrode on a substrate;
forming a silicon nitride layer on the gate electrode at least partially;
forming a silicon oxide layer on the substrate, the gate electrode, and the silicon nitride layer;
etching the silicon oxide layer in a channel region, a region overlapping the gate electrode;
forming an oxide semiconductor pattern on the gate insulating layer, wherein a part of the oxide semiconductor overlaps the gate electrode;
forming a source electrode and a drain electrode on the oxide semiconductor pattern; and
forming an encapsulation layer on the source electrode, the drain electrode, the oxide semiconductor pattern, and the gate insulating layer.

19. The method of claim 18, wherein the etching the silicon oxide layer comprises etching a part of the silicon oxide layer.
